(19) United States
(12) Patent Application Publication
(10) Pub. No.: US 2010/0309221 A1
(43) Pub. Date: Dec. 9, 2010

(54) Display Housing With Slot For Receiving Peripheral Devices

(76) Inventor: Robert L. Myers, Loveland, CO (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/867,486

(22) PCT Filed: Feb. 22, 2008
(86) PCT No.: PCT/US2008/054804

§ 371 Date: Aug. 12, 2010

(51) Int. Cl. G09G 5/00; H05K 5/02; G06F 19/00

(52) U.S. Cl. 345/619; 312/223.1; 702/150; 702/64

(57) ABSTRACT

A system comprises a housing for a display. The housing defines a slot in an exposed surface of the housing. The slot is adapted to receive a peripheral device. The system also comprises a location sensing mechanism in the slot usable to determine a physical location of the peripheral device inserted into the slot.

### BACKGROUND

Many computer users use one or more peripheral devices with their computer systems. Examples of such peripheral devices comprise cameras, speakers, hand-held computers, memory sticks, etc. Connecting the peripheral devices to the computer chassis can be cumbersome as the connectors on the chassis may not be easily accessible, the electrical cables connecting the peripheral devices to the computer can be bothersome, etc. Further, a user interface to enable a user to transfer data between the computer and a peripheral device may also be cumbersome and non-intuitive.

### BRIEF DESCRIPTION OF THE DRAWINGS

For a detailed description of exemplary embodiments of the invention, reference will now be made to the accompanying drawings in which:

FIG. 1 shows a system in accordance with embodiments of the invention;

FIG. 2 shows a side view of the system of FIG. 1 in accordance with embodiments of the invention;

FIG. 3 shows a close-up of a corner of a display shown in the embodiment of FIG. 1;

FIG. 4 illustrates how a peripheral device is mated to a slot provided on the display in accordance with various embodiments;

FIG. 5 illustrates a system having a peripheral device location sensor and computer interface in accordance with various embodiments;

FIG. 6 shows a method in accordance with various embodiments; and

FIG. 7 illustrates a peripheral device post and mounting shoe for a peripheral device that is location-agnostic in accordance with various embodiments.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection. The term “system” refers to a combination of two or more components. A system may comprise, for example, a computer, a monitor, an “all-in-one” computer/display, a combination of computers, or a subsystem within a computer.

### DETAILED DESCRIPTION

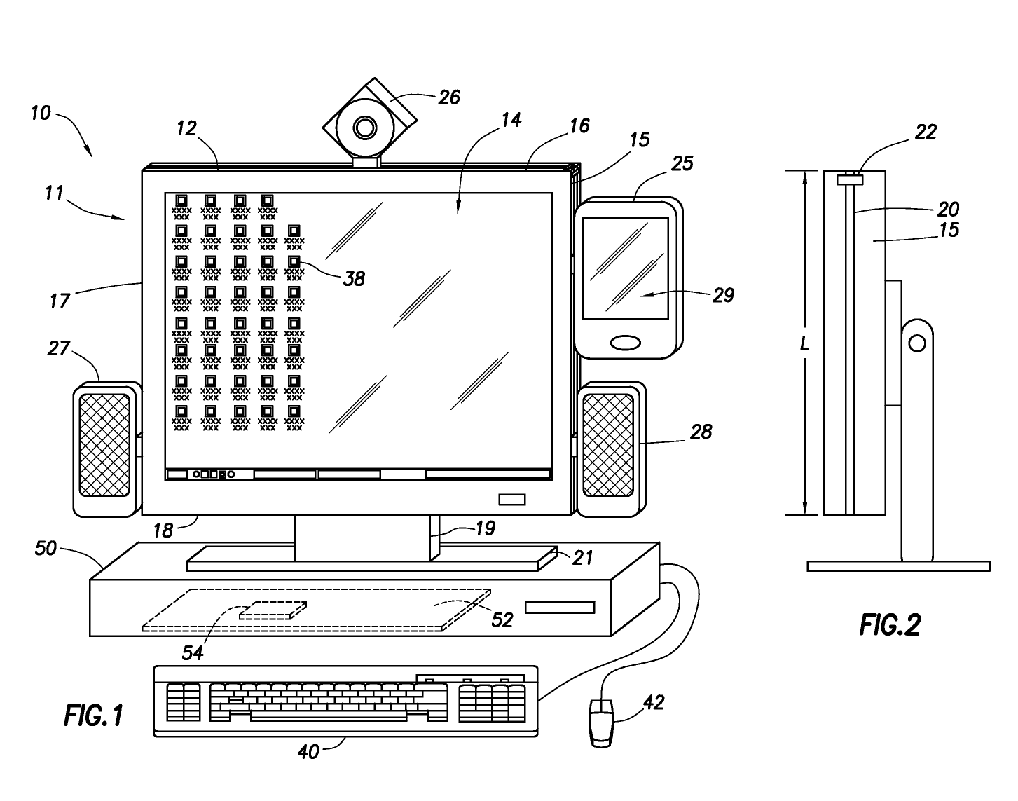

FIG. 1 shows a system 10 in accordance with various embodiments. System comprises a display unit 11 coupled to a chassis 50. The chassis 50 comprises various components such as a system board 52 on which a processor 54 and other electrical components (e.g., memory devices) are mounted. The combination of the display unit 11 and chassis 50 form a computer system, but in other embodiments, the display unit 11 can be used in systems other than computers.

One or more input devices such as a keyboard 40 and pointing device (e.g., mouse) 42 may also be provided. Keyboard 40 and pointing device 42 permits a user to operate the computer system.

In various embodiments, the display unit 11 comprises an electronic display 14 contained within a housing 12. The display 14 may comprise any suitable type of display such as a cathode ray tube (CRT), a liquid crystal display (LCD), etc. One or more graphical icons 38 are shown on display 14 with which the user can interact. Using the keyboard 40 and/or pointing device 42, the user can “click and drag” an icon from one location on the display 14 to another. A user can also double click an icon to play that icon (e.g., to open the associated file or execute the associated software). The display unit 11 also comprises a support column 19 and base 21. The support column 19 supports the housing 12 and display 14 away from the base 21. In some embodiments, the base 21 is adapted to sit on a work surface such as a table or desk. In other embodiments, the base 21 comprises a clamp or other mechanism that enables the display unit 11 to be attached to an edge of a work surface. In yet other embodiments, the base 21 is adapted to enable the display unit 11 to be attached to a wall bracket.

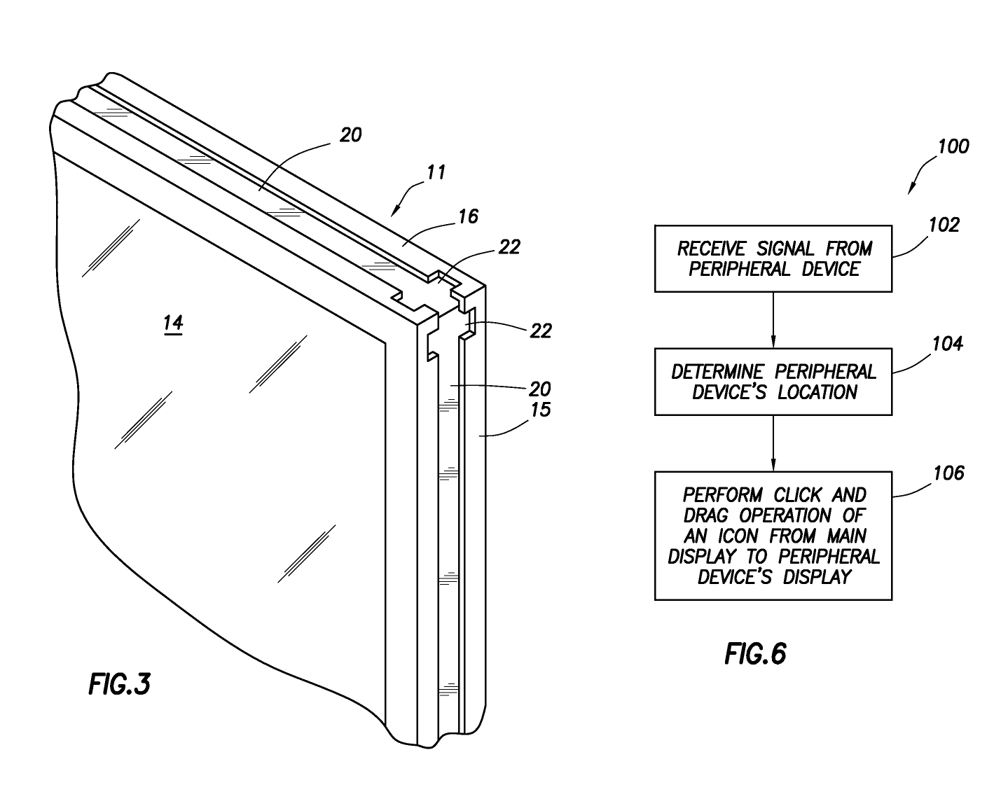

The display housing 12 comprises at least four externally exposed surfaces 15, 16, 17, and 18 (e.g., a first side surface, a top surface, a second side surface, and a bottom surface, respectively). FIG. 2 shows a side view of the display 11. In the view of FIG. 2, side surface 15 is shown. Side surface 15 comprises a slot 20 that, in the illustrative embodiment, substantially extends the length L of side surface 15. One or more mechanical entry points 22 are provided for a peripheral device to be mated to the slot 20 and then slid along the slot to a user-desired position. The slot 20 may extend along just one surface 15-18 or along two or more surfaces. In some embodiments, one continuous slot 20 extends along multiple surfaces. In other embodiments, multiple, separate slots 20 are provided, at least one on a separate surface. In yet other embodiments, more than one slot 20 is provided on each of one or more surfaces 15-18 of the housing 12 and the slots 20 on a common housing surface (e.g., surface 15) are separate from each other. In some embodiments, a slot extends substantially along the entire length L (FIG. 2) of a housing surface, while in other embodiments, the slot extends along one-half or more of the length of the side surface of the housing.

FIG. 1 illustrates four peripheral devices 25, 26, 27, and 28 attached to the display housing 12 in this manner. Peripheral device 25 comprises a hand-held computer. Peripheral device 26 comprises a camera. Peripheral devices 27 and 28 comprise speakers. As used herein, the term peripheral device refers to any device that attaches to and is used in conjunction with the system 10.

FIG. 3 illustrates a partial view of display unit 11. The view of FIG. 3 illustrates portions of orthogonal surfaces 15 (side surface) and 16 (top surface) of the display housing 12. Slot 20 extends along each of surfaces 15 and 16 as shown. In the embodiment shown in FIG. 3, an entry point 22 is provided on each surface 15, 16 to enable a user to mate a peripheral device with the slot 20 that extends along each such surface. Such peripheral devices can then be slid to a user-desired location such as that shown in FIG. 1.

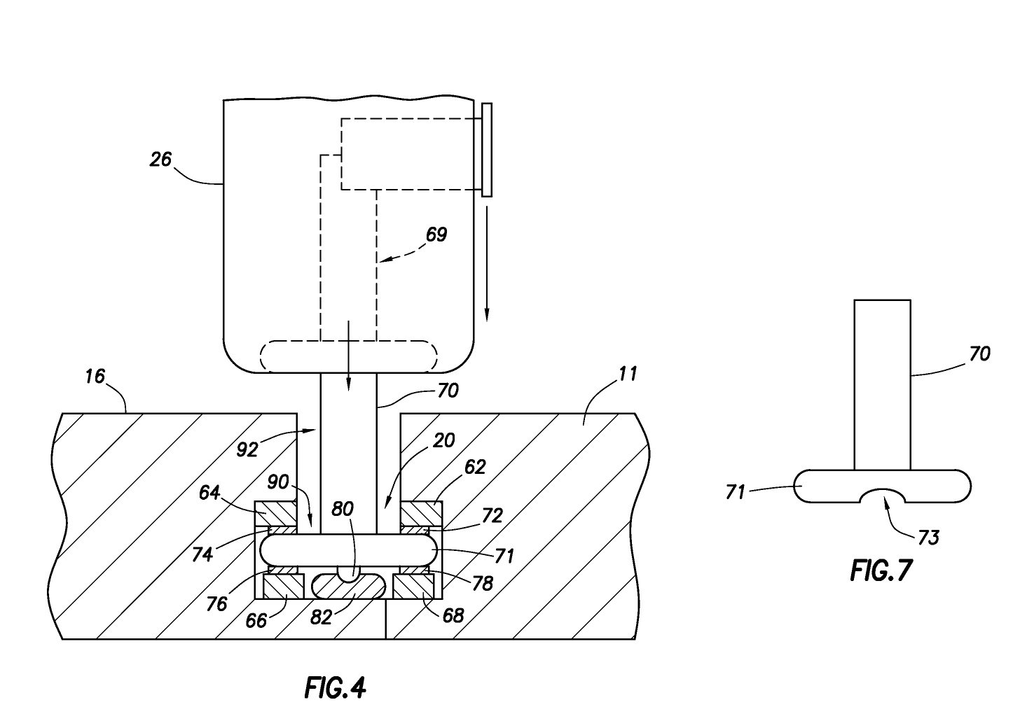

In various embodiments, the slot 20 comprises structure that both mechanically supports the peripheral device as well as provides either or both of power and data connectivity to the peripheral device. FIG. 4 illustrates a cross-sectional view of slot 20 disposed in surface 16 of display unit 11. The slot 20 generally comprises a bore 92 that extends down from exposed surface 16 to a substantially rectangular chamber 90. The peripheral device (peripheral device 26 in the example of FIG. 4, comprises a slot-connecting member 69 that has at least two different positions. In a first position, the slot-connecting member 69 is stored internal to the peripheral device 26 as indicated in dashed lines in FIG. 4. In a second position, the slot-connecting member 69 extends away from the peripheral device as shown and locks in place for insertion into slot 20 of the display unit 11. In some embodiments, the slot-connecting member 69 ejects from the peripheral device by way of a spring (not specifically shown).

The slot-connecting member 69 comprises a post 70 and a mounting shoe 71. The mounting shoe 71 is generally square or rectangular in shape with rounded off corners as desired. The shape and size of the shoe 71 comports with the dimensions of the slot 20 to enable the shoe to fit within and slide along slot, be able to be supported in place by the slot.

The mounting shoe 71 comprises multiple electrical contacts 72, 74, 76, and 78. In the embodiment of FIG. 4, contacts 72 and 74 are provided on one side of the mounting shoe 71 and contacts 76 and 78 are provided on the other side of the shoe. One pair of contacts (e.g., contacts 72 and 74) comprises power and ground contacts, while the other pair of contacts (e.g., contacts 76 and 78) comprises data+ and data− contacts. The slot 20 comprise conductive strips 62, 64, 66, and 68 that are adapted to receive and electrically contact the contacts 72-78 of the mounting shoe 71. For example, contact 72 electrically mates with conductive strip 62, while contacts 74, 76, and 78 electrically mate with conductive strips 64, 66, and 68. Conductive strips 62 and 64 are configured in various embodiments to provide power and ground contact points for the corresponding contacts 72 and 74 of the mounting shoe 71. Conductive strips 66 and 68 are configured to provide data contact points for the corresponding contacts 76 and 78 of the mounting shoe. Thus, by inserting the mounting shoe 71 of the slot-connecting member 69 into the slot 20, the peripheral device 26 is supported in place adjacent the display unit 11, as well as provided with power and data connectivity.

FIG. 4 also illustrates a location sensing mechanism 82 provided in the slot 20. The location sensing mechanism 82 is usable to determine the physical location of the peripheral device inserted into the slot 20. Any of a variety of mechanisms can be implemented for the location sensing mechanism 82. For example, the location sensing mechanism 82 may comprise a resistive strip. A voltage (e.g., 12 VDC) is applied to either end of the resistive strip. The mounting shoe 71 comprises a conductive contact 80 that contacts the resistive strip 82 thereby generating a voltage whose magnitude is a function of where along the resistive strip the mounting shoe's contact 80 contacts the resistive strip. The voltage can be decoded to determine the location of the peripheral device 26 along the slot.

FIG. 5 illustrates a location sensor device 99 that receives the voltage signals from the various peripheral devices and, from the voltages, determines the location of each peripheral device adjacent the display unit 11. The location sensor device 99 may be integrated into the display unit 11 (as illustrated in FIG. 5) or integrated into chassis 50 (FIG. 1). The location sensor 99 determines, using any of the various techniques described herein or other techniques, the location of the various peripheral devices disposed about the outer edges of the display housing 12.

In some embodiments, one continuous resistive strip 82 is provided in a slot 20 that extends around multiple surfaces of the display unit (e.g., 2, 3, or all 4 surfaces). As such, the voltage from a particular peripheral device's contact 80 encodes the location of that peripheral device.

In other embodiments, each surface 15-18 of the display housing 12 comprises a separate slot 20 and each such slot 20 comprises its own resistive strip 82. The voltage (e.g., 12 VDC) applied to each resistive strip 82 may the same as the voltage applied to all other resistive strips. The location sensor device 99 receives multiple input voltages, each input voltage line being associated with a particular resistive strip as is programmed into the location sensor device 99.

In other embodiments, the location sensing mechanism does not electrically contact the shoe 71 of the peripheral device and instead comprises an ultrasonic sound wave generator. Such a sound wave generator may be provided at one end of a slot 20 and may emit sound waves along the slot (e.g., conducted along the material defining the slot). If a peripheral device is present in the slot (i.e., the device's post 70 and/or mounting shoe 71), the sound waves will reflect off of the peripheral device's post 70 and/or mounting shoe 71. The sound wave generator will receive the reflected sound waves, the frequency of which determines the location of the peripheral device along the slot 20.

In yet other embodiments, the location sensing mechanism comprises a time-varying, electrical signal generator. Such an electrical signal generator may be provided at one end of a slot 20 and may emit electrical signals along a conductive strip 82 (or one of the power or data strips 62-68). The electrical signals have a predetermined frequency. If a peripheral device is present in the slot (i.e., the device's post 70 and/or mounting shoe 71), the electrical signals will reflect off of the interface between the conductive strip 28 and the peripheral device's post 70 and/or mounting shoe 71. The electrical signal generator will receive the reflected electrical signals, the frequency of which determines the location of the peripheral device along the slot 20. This embodiment thus uses time domain reflectometry, which is well-known. Reference can be made to US Pat. Pub. 2007/0204686, incorporated herein by reference, for additional detail regarding time domain reflectometry.

FIG. 5 also shows that the various peripheral devices may couple to a common data communication link 81 such as a universal serial bus (USB). The display unit 11 also contains an interface circuit 92 that provides data connectivity between the slot(s) 20 and the peripheral devices mated thereto and host logic in the chassis 50. The interface circuit 92 thus interfaces communication link 81 to the host system.

Determining the location of the various peripheral devices along the outer surfaces 15-18 of the display unit 11 enables any of a variety of actions to be performed based on such determined locations. For example, referring to FIG. 1, a user of the system 10 can “click and drag” an icon (e.g., icon 38) from display 14 to a display of an adjacent peripheral device. For example; peripheral device 25 comprises a display 29. Icon 38 may be dragged by a user, using pointing device 42, from the display area of display 14 to the display area of display 29 as if the displays 14 and 29 combined were one display. By way of another example, FIG. 1 shows left and right speakers 27 and 28, respectively. Determining that speaker 27 is provided on a left-hand side of the display unit 11 (when facing the display unit) and that speaker 28 is provided on the right-hand side, enables an audio subsystem in the chassis 50 provide left and right channel audio the correct speakers.

FIG. 6 illustrates a method 100 in accordance with various embodiments. At 102, method 100 comprises receiving a signal from a peripheral device. The peripheral device has been mated to a slot 20 of the display unit 11 as explained above. The signal received from the peripheral device is processed by the location sensing mechanism 82 to determine the location of the peripheral device (104). At 106, an operation such as a “click and drag” operation of an icon from the display 14 is performed to move the icon from the display 14 to the display of the peripheral device (e.g., display 29).

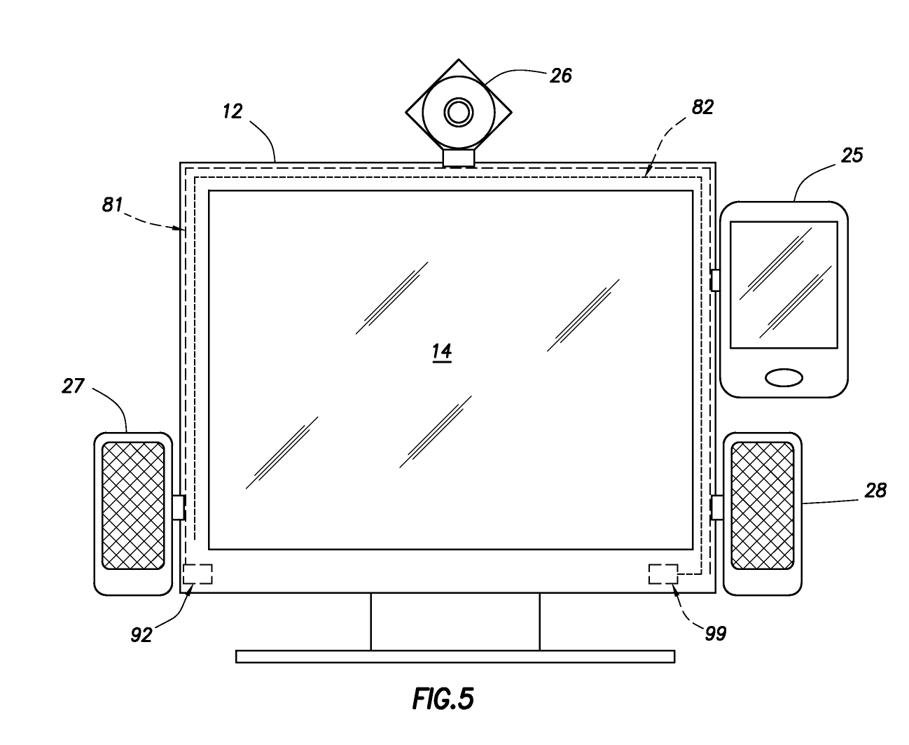

In some embodiments, a peripheral device (such as speakers 27, 28) does not contain a display. For at least some of such peripheral devices, determining the location of the device around the outer edge of the display housing 12 is not needed for the host system to interact with such a peripheral device. FIG. 7 thus illustrates a portion of a peripheral device in which the shoe 71 has a carved out area 73 that prevents the shoe 71 from making contact with the location sensing mechanism 82 (e.g., resistive strip) provided in the slot.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
a housing for a display, said housing defining a slot in an exposed surface of said housing, said slot adapted to receive a peripheral device;
a location sensing mechanism in said slot usable to determine a physical location of said peripheral device inserted into said slot.

2. The system of claim 1 wherein said location sensing mechanism comprises a resistive strip.

3. The system of claim 2 wherein said resistive strip is adapted to electrically couple to the peripheral device and said resistive strip receives a first voltage, and the system further comprises logic that receives a second voltage of the resistive strip at the location of the peripheral device, said logic using said second voltage to determine the location of the peripheral device relative to the housing.

4. The system of claim 1 wherein said location sensing mechanism comprises a plurality of conductive elements insulated from one another.

5. The system of claim 1 wherein said location sensing mechanism comprises an ultrasonic sound wave generator.

6. The system of claim 1 wherein said location sensing mechanism comprises a time-varying electrical signal generator.

7. The system of claim 1 wherein said slot extends along at least one-half of a side of said housing.

8. The system of claim 1 wherein said slot extends along at least sides of said housing.

9. The system of claim 1 further comprising a plurality of slots, each slot being adapted to receive a peripheral device.

10. The system of claim 1 wherein said slot comprises a data bus.

11. The system of claim 1 wherein said slot comprises a power bus.

12. The system of claim 1 further comprising a chassis, containing a processor, coupled to said display housing, said processor causing a graphical icon to be moved from the display in the housing to a display in a peripheral device.

13. A peripheral device, comprising:
a foot comprising a data connection; and
a biasing member that forces said foot outward
wherein said foot is adapted to fit in a slot in a display housing, said foot enabling said peripheral device to couple to an electrical bus in said slot.

14. The peripheral device of claim 13 further comprising logic that receives a signal from a location sensing element in said strip, said logic determining location of said peripheral device relative to said slot.

15. The peripheral device of claim 14 wherein said logic transmits a value indicative of said location to logic contained in the display housing.

16. The peripheral device of claim 13 wherein said foot comprises a power connection that receives power from a power bus in said slot.

17. The peripheral device of claim 13 wherein said foot comprises a data connection that receives data from, or provides data to, a data bus in said slot.

18. A method, comprising:
receiving a signal from a peripheral device attached to a display housing; and
determining a location of said peripheral device relative to said display housing using said signal.

19. The method of claim 18 further comprising causing an icon on a display contained in said display housing to move from said display to a display on said peripheral device.

20. The method of claim 18 further comprising using said location to cause an icon on a display contained in said display housing to move from said display to a display on said peripheral device.
